(19) United States
(12) Patent Application Publication
(10) Pub. No.: US 2015/0219726 A1
(43) Pub. Date: Aug. 6, 2015

(54) SYSTEMS AND METHODS FOR BATTERY STATE ESTIMATION

(71) Applicant: GM GLOBAL TECHNOLOGY OPERATIONS LLC, Detroit, MI (US)

(72) Inventors: JOCHEN LENZ, HATTERSHEIM (DE); ROBERT C. BARASZU, DEARBORN, MI (US)

(73) Assignee: GM GLOBAL TECHNOLOGY OPERATIONS LLC, Detroit, MI (US)

(21) Appl. No.: 14/171,334

(22) Filed: Feb. 3, 2014

(51) Int. Cl. G01R 31/36

(52) U.S. Cl. CPC G01R 31/3648; G01R 31/3606

(57) ABSTRACT

System and methods for estimating a state of a battery utilizing an adaptive battery model are presented. The model may utilize a multi-RC electric circuit model designed to represent an open circuit voltage and/or an impedance of an actual battery system. A state observer may be utilized in connection with estimating parameters associated with a model of the battery system (e.g., resistances in the multi-RC circuit model). Systems and methods disclosed herein may further employ a blending technique utilizing an Ah-based SOC determination and an OCV-based SOC determination in estimating a state of a battery system.

### TECHNICAL FIELD

This disclosure relates to systems and methods for estimating a state of a battery system, including a state of charge (“SOC”) and/or a state of health (“SOH”) of a battery system. More specifically, but not exclusively, the systems and methods disclosed herein relate to estimating a state of a battery system for control and/or diagnostic purposes utilizing an adaptive battery model.

### BACKGROUND

Passenger vehicles often include electric batteries for operating features of a vehicle's electrical and drivetrain systems. For example, vehicles commonly include a 12V lead-acid automotive battery configured to supply electric energy to vehicle starter systems (e.g., a starter motor), lighting systems, and/or ignition systems. In electric, fuel cell (“FC”), and/or hybrid vehicles, a high voltage (“HV”) battery system (e.g., a 360V HV battery system) may be used to power electric drivetrain components of the vehicle (e.g., electric drive motors and the like). For example, an HV rechargeable energy storage system (“ESS”) included in a vehicle may be used to power electric drivetrain components of the vehicle.

Monitoring a state of a battery system may allow for more accurate battery system control and/or management decisions to be made based on such information, thereby improving overall battery performance. Further, accurate knowledge of the state of a battery system may allow for improved diagnostics and/or prognostic methods to identify potential battery systems issues. Conventional methods for determining a state of a battery system, however, may be less accurate, thereby detrimentally affecting battery system control, management, and diagnostic decisions based on such state information.

### SUMMARY

Systems and methods disclosed herein may provide for more accurate determination and/or estimations of a state of a battery system, thereby improving battery system control, management, and diagnostic decisions. In certain embodiments, the systems and methods disclosed herein may utilize an adaptive model for determining and/or estimating a state of a battery system. In certain embodiments, the adaptive model may allow for correct modelling of voltage at a battery terminal. The model may utilize a voltage source and a multi-RC electric circuit designed to represent an open circuit voltage and/or an impedance of an actual battery system. A state observer utilizing a frequency domain monitoring technique (e.g., an approximative real-time Fourier conversion frequency domain monitoring technique) may be utilized in connection with estimating parameters associated with a model of the battery system (e.g., resistances in the multi-RC circuit model). In certain embodiments, the parameter estimator may comprise a Luenberger observer. Systems and methods disclosed herein may further employ a blending technique utilizing an Ah-based SOC determination and an open circuit voltage-based SOC determination in estimating a state of a battery system.

Certain embodiments disclosed herein may allow processing resources (e.g., battery control unit) to be used more efficiently, allowing state determinations and/or estimations to be performed on single battery cells (e.g., individually). Embodiments of the methods disclosed herein may provide more accurate and adjustable state determination and battery system modeling. In certain embodiments, battery systems models may be scalable (e.g., a number and time constant of RC elements may be adjusted) to a particular modelling frequency range. In some embodiments, the lower end of this frequency-range may be given by a typical driving/operating-cycle duration, and the higher end may be given by a sampling frequency.

In certain embodiments, a method for determining a state of a battery system (e.g., a SOC) may include receiving a current measurement signal from a subdivision of a battery system (e.g., a battery cell or pack). A difference signal associated with a difference between a measured terminal voltage of the subdivision system and a modeled terminal voltage of the battery subdivision may also be received.

The modeled terminal voltage of the battery system may be provided by a model of the battery subdivision. In certain embodiments, the model of the subdivision may comprise a multi-RC circuit model that includes a plurality of paired resistors and capacitors. Each pair of resistors and capacitors may have a predefined time constant. Further, each of the plurality of resistors may have resistances estimated based, to some degree, on the difference between measured and modeled terminal voltages. In certain embodiments, the resistances may be estimated using a state observer that, in some embodiments, may comprise a Luenberger observer.

A correction to the received current measurement signal may be applied for SOC correction, based, at least in part, on the difference between the measured and modelled terminal voltage. A state of the subdivision may be estimated based on the corrected current measurement signal.

### BRIEF DESCRIPTION OF THE DRAWINGS

Non-limiting and non-exhaustive embodiments of the disclosure are described, including various embodiments of the disclosure with reference to the figures, in which:

FIG. 1 illustrates an exemplary system for monitoring a state of a battery system in a vehicle consistent with embodiments disclosed herein.

FIG. 2 illustrates a conceptual block diagram of a system for monitoring a state of a battery system consistent with embodiments disclosed herein.

FIG. 3 illustrates a multi-RC model for modeling a battery system consistent with embodiments disclosed herein.

FIG. 4a illustrates a conceptual diagram of an approximative real-time Fourier conversion method consistent with embodiments disclosed herein.

FIG. 4b illustrates a conceptual timing schedule for an approximative real-time Fourier conversion method consistent with embodiments disclosed herein.

FIG. 5 illustrates a state observer consistent with embodiments disclosed herein.

FIG. 6 illustrates a functional block diagram of a weighted system for determining an SOC consistent with embodiments disclosed herein.

FIG. 7 illustrates a flow chart of an exemplary method for determining a state of a battery system consistent with embodiments disclosed herein.

FIG. 8 illustrates an exemplary system for implementing certain embodiments of the systems and methods disclosed herein.

### DETAILED DESCRIPTION

A detailed description of systems and methods consistent with embodiments of the present disclosure is provided below. While several embodiments are described, it should be understood that the disclosure is not limited to any one embodiment, but instead encompasses numerous alternatives, modifications, and equivalents. In addition, while numerous specific details are set forth in the following description in order to provide a thorough understanding of the embodiments disclosed herein, some embodiments can be practiced without some or all of these details. Moreover, for the purpose of clarity, certain technical material that is known in the related art has not been described in detail in order to avoid unnecessarily obscuring the disclosure.

The embodiments of the disclosure will be best understood by reference to the drawings, wherein like parts may be designated by like numerals. The components of the disclosed embodiments, as generally described and illustrated in the figures herein, could be arranged and designed in a wide variety of different configurations. Thus, the following detailed description of the embodiments of the systems and methods of the disclosure is not intended to limit the scope of the disclosure, as claimed, but is merely representative of possible embodiments of the disclosure. In addition, the steps of a method do not necessarily need to be executed in any specific order, or even sequentially, nor need the steps be executed only once, unless otherwise specified.

Battery system state information may be utilized in connection with a battery system model and may include, without limitation, open circuit voltages, resistor values, capacitor values, etc.). Such state information may be utilized in a variety of contexts including, without limitation, battery system management, operation, diagnostic, and prognostic decisions. Such state information may be used to better utilize a battery system. For example, knowledge of a SOC and/or a SOH of a battery system may be utilized to optimize the performance of the battery system. In certain embodiments, a battery system's SOH may be a qualitative measure of a battery system's ability to store and deliver electrical energy, while a battery system's SOC may be a measure of electrical energy stored in the battery system.

The systems and methods disclosed herein may allow improvements in battery state determination and/or estimation. In some embodiments, adaptation to changes resulting from battery system age, battery variations, and operating conditions (e.g. temperature and SOC) may be realized. Still further, improvements in state determination accuracy and/or computation speed may be realized based on improved models, improved adaptation, and/or improved efficiency in generating an estimate of a state of the battery system. As a result of improved accuracy in estimating a state of a battery system, a variety of benefits may be realized including, without limitation, improvements in battery system management and/or control, prolonged battery system life, reduced cost of battery system replacement, and reduced calibration to account for variations among individual battery systems.

In certain embodiments, the systems and methods disclosed herein may utilize an adaptive model for estimating a state of a battery system. The model may utilize an electric circuit designed to represent an open circuit voltage (“OCV”) and an impedance of an actual battery system using a plurality of RC pairs. A state observer utilizing an approximative real-time Fourier conversion (“ARTFC”) frequency domain monitoring technique may be utilized in connection with determining a state of a battery system (e.g., in estimating parameters associated with a model of the battery system). In certain embodiments, the state observer may comprise a Luenberger observer. Systems and methods disclosed herein may further employ a blending technique utilizing an Ah-based SOC determination and an OCV-based SOC correction. Although described herein as being utilized in connection with determining SOC of a battery system, it will be appreciated that the systems and methods disclosed herein may also be utilized in connection with determining a variety of other parameters relating to a battery system (e.g., SOH, state of function, power capability, capacity degradation, etc.).

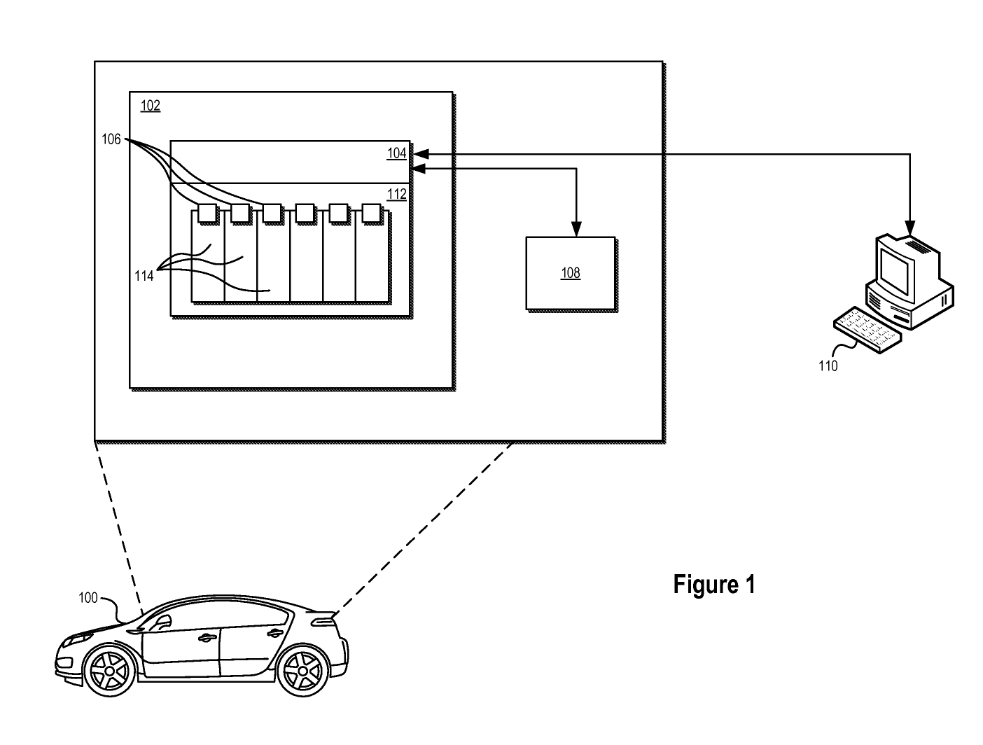

FIG. 1 illustrates an exemplary system for monitoring a state of a battery system 102 in a vehicle 100 consistent with embodiments disclosed herein. The vehicle 100 may be a motor vehicle, a marine vehicle, an aircraft, and/or any other type of vehicle, and may include an internal combustion engine (“ICE”) drivetrain, an electric motor drivetrain, a hybrid engine drivetrain, an FC drivetrain, and/or any other type of drivetrain suitable for incorporating the systems and methods disclosed herein. The vehicle 100 may include a battery system 102 that, in certain embodiments, may be an HV battery system. The HV battery system may be used to power electric drivetrain components (e.g., as in an electric, hybrid, or FC power system). In further embodiments, the battery system 102 may be a low voltage battery (e.g., a lead-acid 12V automotive battery) and may be configured to supply electric energy to a variety of vehicle 100 systems including, for example, vehicle starter systems (e.g., a starter motor), lighting systems, ignition systems, and/or the like.

The battery system 102 may include a battery control system 104. The battery control system 104 may be configured to monitor and control certain operations of the battery system 102. For example, the battery control system 104 may be configured to monitor and control charging and discharging operations of the battery system 102. In certain embodiments, the battery control system 104 may be utilized in connection with the methods disclosed herein to determine a state of the battery system. In certain embodiments, the battery control system 104 may be communicatively coupled with one or more sensors 106 (e.g., voltage sensors, current sensors, and/or the like, etc.) and/or other systems (e.g., vehicle computer system 108) configured to enable the battery control system 104 to monitor and control operations of the battery system 102. For example, sensors 106 may provide battery control system 104 with information used to estimate a SOC and/or a SOH, estimate an impedance, measure a current, and/or measure voltage of a battery pack 112 and/or the battery cells 114.

The battery control system 104 may further be configured to provide information to and/or receive information from other systems (e.g., vehicle computer system 108) included in the vehicle 100. For example, the battery control system 104 may be communicatively coupled with an internal vehicle computer system 108 and/or an external computer system 110 (e.g., via a wired and/or wireless telecommunications system or the like). In certain embodiments, the battery control system 104 may be configured, at least in part, to provide information regarding the battery system 102 (e.g., information measured by sensors 106 and/or determined by control system 104) to a user, service personnel, and/or the like of the vehicle 100, vehicle computer system 108, and/or external computer system 110. Such information may include, for example, battery SOC and/or SOH information, battery operating time information, battery operating temperature information, and/or any other information regarding the battery system 102.

The battery system 102 may include one or more battery pack 112 suitably sized to provide electrical power to the vehicle 100. Each battery pack 112 may include one or more battery cells 114. The battery cells 114 may utilize any suitable battery technology or combination thereof. Suitable battery technologies may include, for example, lead-acid, nickel-metal hydride (“NiMH”), lithium-ion (“Li-Ion”), Li-Ion polymer, zinc-air, lithium-air, nickel-cadmium (“NiCad”), valve-regulated lead-acid (“VRLA”) including absorbed glass mat (“AGM”), nickel-zinc (“NiZn”), molten salt (e.g., a ZEBRA battery), and/or other suitable battery technologies. Each cell 114 may be associated with sensors 106 configured to measure one or more parameters (e.g., voltage, current, temperature, etc.) associated with each battery cell 114. Although FIG. 1 illustrates separate sensors 106 associated with each battery cell 114, in some embodiments a sensor configured to measure various electrical parameters associated with a plurality of cells 114 may also be utilized.

The electrical parameters measured by sensors 106 may be provided to battery control system 104 and/or one or more other systems. Using the electrical parameters, battery control system 104 and/or any other suitable system may coordinate the operation of battery system 102 (e.g., charging operations, discharging operations, balancing operations, etc.). In certain embodiments, one or more electrical parameters may be provided by battery control system 104 and/or one or more sensors 106 to vehicle computer system 108, and/or external computer system 110. Based on certain measured electrical parameters, battery control system 104, vehicle computer system 108, and/or any other suitable system may calculate a state of the battery system 102 and/or any of its constituent cells 114 utilizing methods disclosed herein.

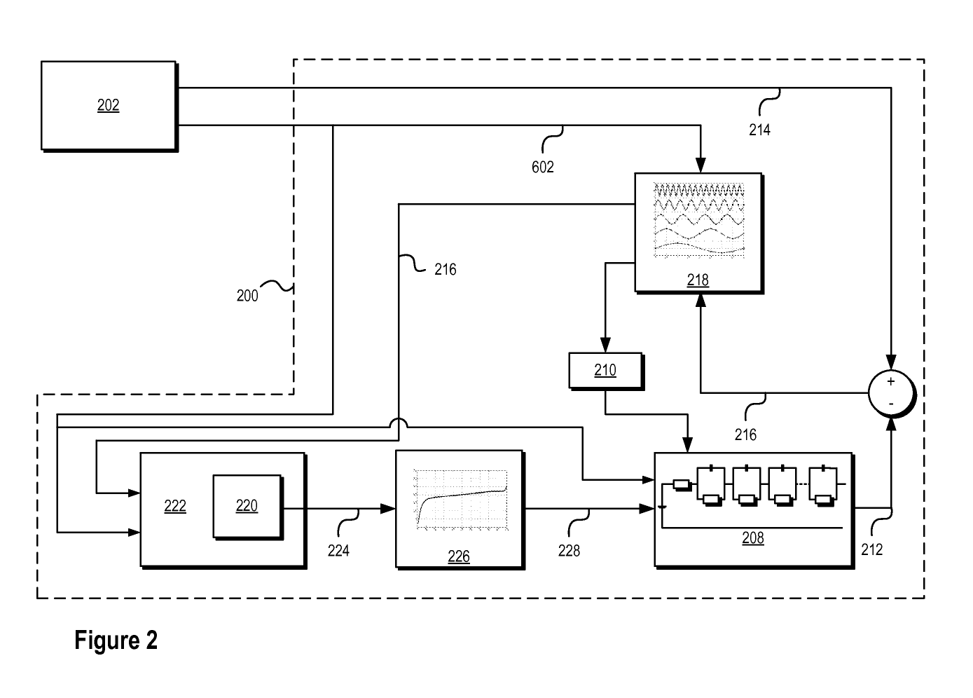

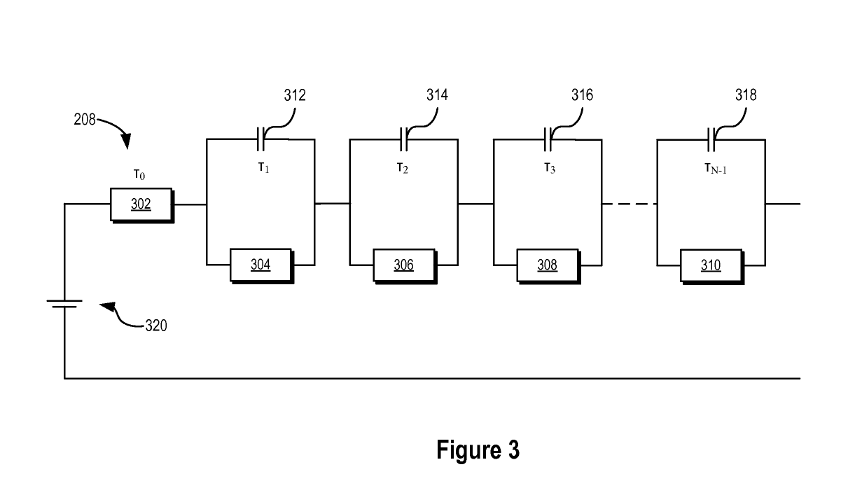

FIG. 2 illustrates a conceptual block diagram of a system 200 for monitoring a state of a battery pack 202 consistent with embodiments disclosed herein. In certain embodiments, one or more elements of the system 200 may be included as part of a battery control system, a vehicle computer system, and/or any other system and/or combination of systems. Certain elements of system 200 illustrated in FIG. 2 are discussed below in more detail in reference to FIGS. 3-6.

In some embodiments, the system 200 may be embodied using a computer system (e.g., an electronic control unit (“ECU”)) executing software methods implementing the systems and methods disclosed herein. The system 200 may utilize a state observer in determining a state of the battery pack 202. The state observer may provide an estimate of the internal state of the battery pack 202 based on measured parameters (e.g., voltages and/or currents). In certain embodiments, the state observer may be configured to populate a parameter matrix 210 with information utilized in estimating a state of the battery system 202, such as resistances included in a circuit model 208. Consistent with embodiments disclosed herein, the state observer may comprise a Luenberger observer, although it will be appreciated that other suitable types of state observers may also be utilized in connection with embodiments of the systems and methods disclosed herein.

In certain embodiments, the battery pack 202 may be modeled by a circuit model 208. Consistent with embodiments disclosed herein, the circuit model 208 may employ a multi-RC design having defined (e.g., predefined) time constants. The multi-RC circuit model 208 may be designed to model an OCV and/or an impedance of the actual battery pack 202. Utilizing a multi-RC circuit model 208 may, among other things, reduce computational requirements for state and/or parameter determinations and/or may allow for modeling the impedance over a wide frequency range. In certain embodiments, the multi-RC circuit model 208 may be utilized to determine a modeled voltage 212 based on a modeled OCV 228 and a modelled impedance, given by its defined time constants and R-parameters.

A difference 216 between the modeled voltage 212 and a measured voltage 214 of the actual battery pack 202 may be calculated and provided to an ARTFC module 218. Further, a current signal 602 may be provided to the ARTFC module 218. The ARTFC module 218 may convert it into an associated frequency domain signal. An AC component of the frequency domain signal may be provided to parameter matrix 210 that, in certain embodiments, may be a Luenberger matrix, to update R-parameters of the multi-RC circuit model 208. A DC component 216 of the frequency domain signal may be provided to a SOC model 222 for use in connection with performing a voltage-based correction.

In some embodiments, the system 200 may employ a blending technique utilizing an Ah-based SOC determination and an OCV-based SOC correction in estimating a state of the battery pack 202. For example, a measured current signal of the battery pack 202 may be provided to an Ampere-hour (“Ah”) calculation module 220 configured to calculate and output an associated Ah signal. This signal, along with a DC voltage difference signal 216 may be provided to a blending module 222 configured to output an associated SOC signal 224. The DC voltage difference signal 216 may be utilized as a voltage-based Ah-correction signal, and the Ah signal provided by the Ah calculation module 220 may be offset accordingly in calculating the SOC signal 224.

In certain embodiments, the SOC signal 224 may be provided to a lookup table 226. This lookup table may represent a specific characteristic of a particular cell type. In some embodiments, the lookup table 226 may convert a given SOC signal 224 into a corresponding steady-state OCV 228.

FIG. 3 illustrates a multi-RC circuit model 208 for modeling a battery system consistent with embodiments disclosed herein. As discussed above, the multi-RC circuit model 208 may be designed to model an OCV and an impedance of an actual battery system to generate a modeled voltage. In certain embodiments, the multi-RC circuit model 208 may comprise a plurality of resistors 302-310 having resistances R₀-R_{N-1} and a plurality of capacitors 312-318 forming associated time constants T₁-T_{N-1} with the resistors 302-310. Resistors 304-310 may be disposed in parallel respectively with capacitors 312-318, with each resistor and capacitor pair (e.g., 304 and 312, 306 and 314, 308 and 316, and 310 and 318) being disposed in series.

In some embodiments, time constants T₀-T_{N-1} may be defined (e.g., predefined). Defining time constants T₀-T_{N-1} may, among other things, define a frequency range in which the impedance of the model 208 can be adapted to the real impedance of the battery pack. In certain embodiments, a characteristic cut-off frequency for each RC-pair may be expressed according to Equation 1, provided below. In certain embodiments, the plurality of time-constants may result in a certain range and granularity for the frequency range:

$${f}_{n} = \frac{1}{2 π {τ}_{n}} \qquad Equation 1$$

Resistances R₀-R_{N-1} of resistors 304-310 in the multi-RC circuit model 208 may be estimated using a variety of techniques including, for example, using a state observer consistent with embodiments disclosed herein, as discussed in more detail below. In certain embodiments, resistances R₀-R_{N-1} of resistors 304-310 may be either pre-estimated (e.g., using look-up table as function of temperature, or the like), estimated in real-time, and/or using any combination thereof.

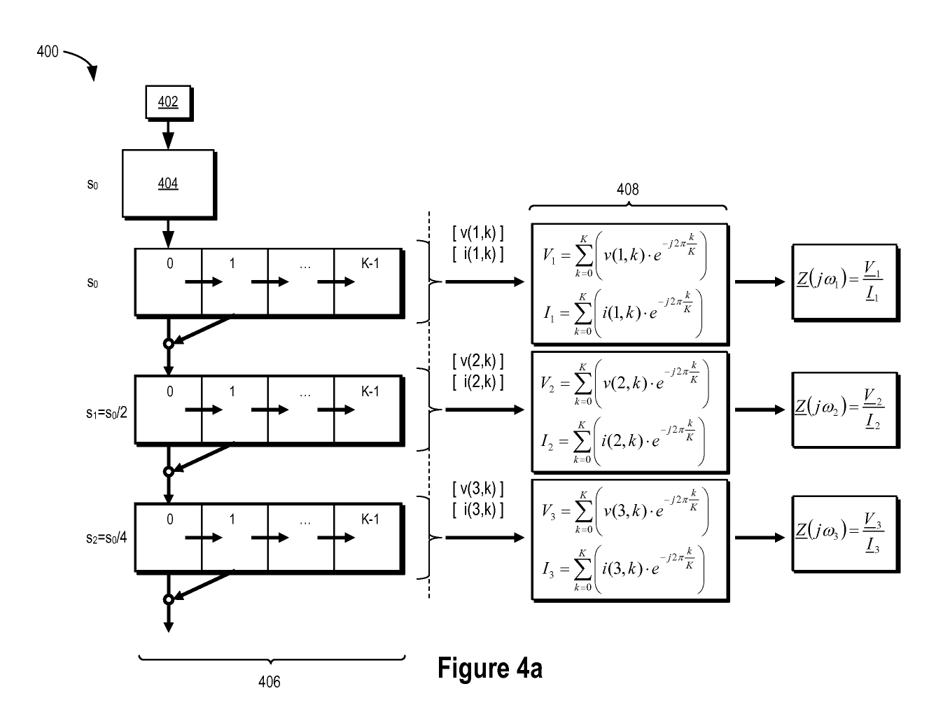

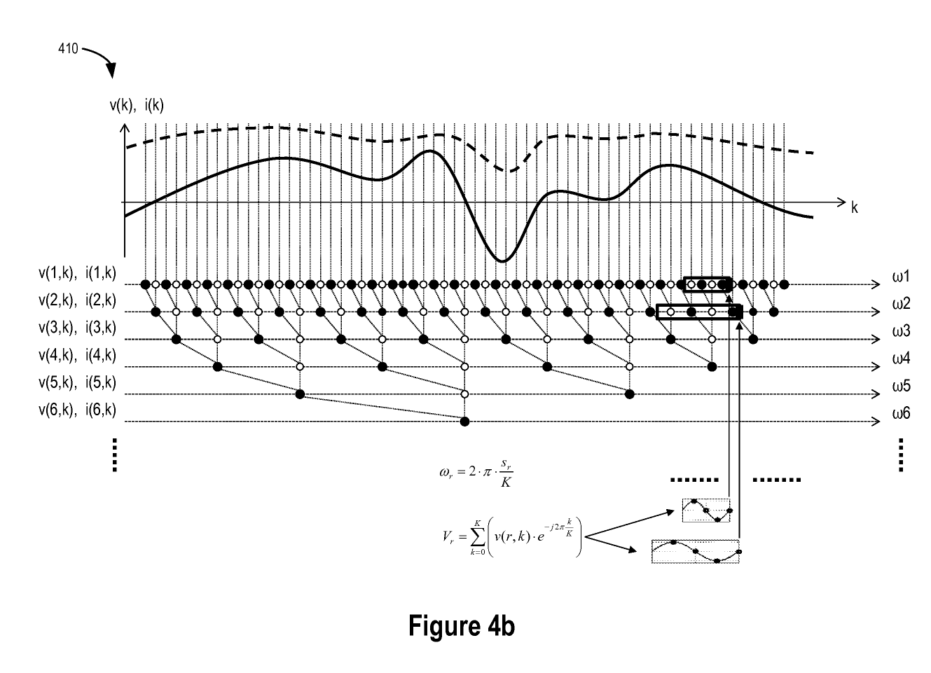

FIG. 4a illustrates a conceptual diagram 400 of an ARTFC method consistent with embodiments disclosed herein. An ARTFC is similar to a Fast Fourier Transformation (“FFT”) in certain aspects. FFT may transform a representation of a signal from a time domain into a frequency domain without loss of information. When transformed back, the original representation may be restored. ARTFC, however, may be a more lossy conversion from a time domain to a frequency domain. When transformed from a time domain to a frequency domain using ARTFC, an original signal may not be restored completely as there is less information in the ARTFC generated frequency-domain representation.

For purposes of implementing embodiments of the systems and methods disclosed herein, full-content in the frequency representation of a system may not be needed and, accordingly, ARTFC may be utilized. For example, a signal which has been converted to a frequency representation by FFT may include a base frequency f₀ (i.e., a first harmonic) as well as higher harmonics f₀*[1, 2, 3, 4, . . . L]. A signal converted to a frequency representation by ARTFC may have power-of-two frequency stepping (i.e., f₀*[1, 2, 4, 8, . . . 2^{L}]. For implementing the disclosed embodiments, this power-of-two frequency stepping may be sufficient as an estimated impedance and may be well-described by a power-of-two frequency stepping and accurate absolute value may not be needed in comparing whether two signals have a positive or negative difference.

The illustrated ARTFC diagram 400 may receive current and voltage signals from current and voltage sensors 402. These signals by be converted to corresponding digital representations by analog-to-digital converter 404 at a sample rate of s₀. Sample values for current i(k) and voltage v(k) may be passed into a first cell (i.e., cell “0”) of a buffer array 406. The buffer array 406 may function as a shift register and previous content of the buffer array 406 may be shifted. A next shift register of the buffer array 406 may be updated at a sample rate of s₁=s₀/2. The input to this shift register may be an average value of buffer array 406 cell “0” and “cell 1” of the first shift register. In this manner, the buffer array 406 may comprise a plurality of horizontal shift registers, where each shift register is updated at half the rate as the preceding shift register and the input for each shift register may be the average of cell “0” and cell “1” from the preceding shift register. In some embodiments, the shift registers may have the same length (i.e., K).

Content from each shift register (i.e., v(k) and i(k) may be passed to a Fourier calculation 408 at a rate that is half of the register update rate. Accordingly, the Fourier calculations may be performed on every second register update step. The Fourier calculations may provide a result for a first harmonic. The frequency of the first harmonic of each Fourier calculation may be fₙ=sₙ/K or ωₙ=2πsₙ/K. Accordingly, by selecting a number and length of the shift registers and associated sample rates, the frequency steps of the calculations may be defined. Results of the Fourier calculations may be provided as an AC output from an associated ARTFC module, representing a difference of impedance at frequencies “fₙ”.

FIG. 4b illustrates a conceptual timing schedule 410 for an ARTFC method consistent with embodiments disclosed herein. In the illustrated timing schedule, input signals v(k) and i(k) may be sampled at a sample rate of s₀. Slower sample rates (i.e., s₁, s₂, . . . etc.) may be associated with a shift register, as discussed above in connection with FIG. 4a. In the illustrated timing schedule 410, the second steps of each sample rate (represented in the illustration by solid dots) indicate a step in time when register content is passed to a Fourier calculation.

As illustrated in timing schedule 410, a calculation may be performed each time step. This may help to distribute processing activity and CPU usage over time allowing for real time computation. Moreover, results for higher frequencies may be provided faster and more often than results for lower frequencies. In certain embodiments, the ARTFC method may output an impedance vector calculated by dividing Fourier coefficients for voltage by Fourier coefficients for current (i.e., Z(jω)=V(jω)/I(jω)). An AC output of an associated ARTFC module may comprise a vector generated based on values of the calculated impedances.

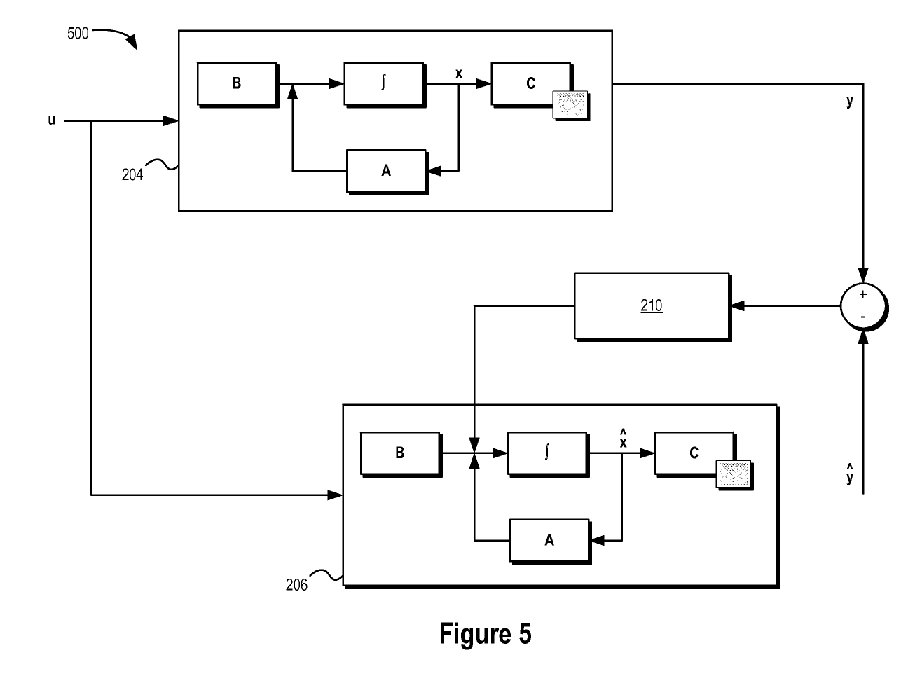

FIG. 5 illustrates a state observer 500 consistent with embodiments disclosed herein. In certain embodiments, the state observer 500 may be utilized in connection with determining and/or estimating a state of a battery system based on one or more measured parameters (e.g., voltages and/or currents) and/or other inputs/outputs of the battery system. In some embodiments, the state observer 500 may comprise a Luenberger observer. In certain embodiments, the state observer 500 may be utilized in connection with estimating one or more resistances to be utilized in a model of an actual battery system by modeling resistor parameters as states which change over time. Among other things, the state observer 500 may allow for dynamic adjustment of such resistances based on actual battery system behavior, thereby improving the accuracy of the model in modeling battery system behavior.

The state observer 500 may include a first component 204 and a second component 206, both of which may be state space representations. The first component 204 of the state observer may be associated with the actual battery system (i.e., a real world battery system), while the second component 206 of the state observer may be associated with a model of the battery system. The first component 204 may be associated with a linear state-space representation of the actual battery system and the second component 206 may be associated with a linear state-space representation of the model of the battery system. In the illustrated state observer 500, “x” and “\hat{x}” is the internal state, “y” and “ŷ” is the output, and “u” is the input. Each component may include [A], [B], and [C] matrices that, if the model of the actual battery system is relatively accurate, should be the same or similar.

In certain embodiments, the state observer 500 may be configured to populate a parameter matrix 210 with information utilized in estimating a state of the battery system 202, such as resistances included in the battery system model. In certain embodiments, the parameter matrix 210 may comprise a Luenberger feedback matrix used to make an internal state of the model 206 equal to a real state by monitoring outputs Resistances (e.g., R_{N}) of the battery system model may be considered as states in connection with the state observer 500. Due to the nature of the battery system model, the resistances may not be dependent on input values “u” and also have no relaxation. Accordingly, the A and B matrices of the state observer 500 may both be zero (e.g., [A]=[0] and [B]=[0]).

In connection with the state observer 500, state vectors for the actual real-world battery system [x] and the modeled battery system [\hat{x}] may be expressed according to Equations 2 and 3:

$$\begin{matrix}x = [ \begin{matrix}{R}_{0} \\ {R}_{1} \\ ⋯ \\ {R}_{N - 1}\end{matrix} ] & Equation 2 \\ \hat{x} = [ \begin{matrix}{\hat{R}}_{0} \\ {\hat{R}}_{1} \\ ⋯ \\ {\hat{R}}_{N - 1}\end{matrix} ] & Equation 3\end{matrix}$$

where R_{N} represents resistances of the actual battery system and \hat{R}_{N} represents resistances of the battery system model.

Output vectors for the actual battery system [y] and the modeled battery system [ŷ] may be expressed according to Equations 4 and 5:

$$\begin{matrix}y = [ \begin{matrix}{\underline{Z}}_{1} \\ {\underline{Z}}_{2} \\ ⋯ \\ {\underline{Z}}_{R}\end{matrix} ] & Equation 4 \\ \hat{y} = [ \begin{matrix}{\underline{\hat{Z}}}_{1} \\ {\underline{\hat{Z}}}_{2} \\ ⋯ \\ {\underline{\hat{Z}}}_{R}\end{matrix} ] & Equation 5\end{matrix}$$

where Z_{R} represents complex impedances of the actual battery system (i.e., Z_{R}=Z(jω_{R})) and \hat{Z}_{R} represents complex impedances of the battery system model (i.e., \hat{Z}_{R}=\hat{Z}(jω_{R})).

The [C] matrix for the real system 204 and the model 206 may be the same and/or similar and may utilize defined (e.g., predefined) parameters ω and τ. In some embodiments, the [C] matrix may be expressed according to Equation 6:

$$[ C ] = [ \hat{C} ] = [ \begin{matrix}\frac{1}{1 + j {ω}_{1} {τ}_{0}} & \frac{1}{1 + j {ω}_{1} {τ}_{1}} & ⋯ & \frac{1}{1 + j {ω}_{1} {τ}_{N - 1}} \\ \frac{1}{1 + j {ω}_{2} {τ}_{0}} & \frac{1}{1 + j {ω}_{2} {τ}_{1}} & ⋯ & \frac{1}{1 + j {ω}_{2} {τ}_{N - 1}} \\ ⋯ & ⋯ & & ⋯ \\ \frac{1}{1 + j {ω}_{R} {τ}_{0}} & \frac{1}{1 + j {ω}_{R} {τ}_{1}} & ⋯ & \frac{1}{1 + j {ω}_{R} {τ}_{N - 1}}\end{matrix} ] \qquad Equation 6$$

Impedances of the battery system and model may be based on FIG. 3 and expressed according to Equation 7:

$$\begin{matrix}[ \begin{matrix}{\underline{Z}}_{1} \\ {\underline{Z}}_{2} \\ ⋯ \\ {\underline{\hat{Z}}}_{R}\end{matrix} ] = [ \begin{matrix}\frac{1}{1 + j {ω}_{1} {τ}_{0}} & \frac{1}{1 + j {ω}_{1} {τ}_{1}} & ⋯ & \frac{1}{1 + j {ω}_{1} {τ}_{N - 1}} \\ \frac{1}{1 + j {ω}_{2} {τ}_{0}} & \frac{1}{1 + j {ω}_{2} {τ}_{1}} & ⋯ & \frac{1}{1 + j {ω}_{2} {τ}_{N - 1}} \\ ⋯ & ⋯ & & ⋯ \\ \frac{1}{1 + j {ω}_{R} {τ}_{0}} & \frac{1}{1 + j {ω}_{R} {τ}_{1}} & ⋯ & \frac{1}{1 + j {ω}_{R} {τ}_{N - 1}}\end{matrix} ] \cdot \\ [ \begin{matrix}{R}_{0} \\ {R}_{1} \\ ⋯ \\ {R}_{N - 1}\end{matrix} ]\end{matrix} \qquad Equation 7$$

In other words, [Z]=[y]=[C] [x] with [x]=[R] and [\hat{Z}]=[ŷ]=[C] [\hat{x}]=[C][\hat{R}].
Parameter matrix 210, which in certain embodiments may comprise a Luenberger matrix, may be populated such that a complex eigen (F) of the matrix has negative real parts. In certain embodiments, this design rule may be expressed according to Equation 8:

F=A−LC
A=[0]
Re{eigen(F)}<0

Re{eigen(−LC)}<0 Equation 8

The input to the matrix 210 may be a vector of impedance differences at several frequencies (e.g., ΔZ(jω)), and the output may be used to correct the model resistances [\hat{R}]. The parameter matrix 210 may be populated diagonally, so that high frequencies may estimate the faster RC pairs, whereas low frequencies may estimate the slower RC pairs.

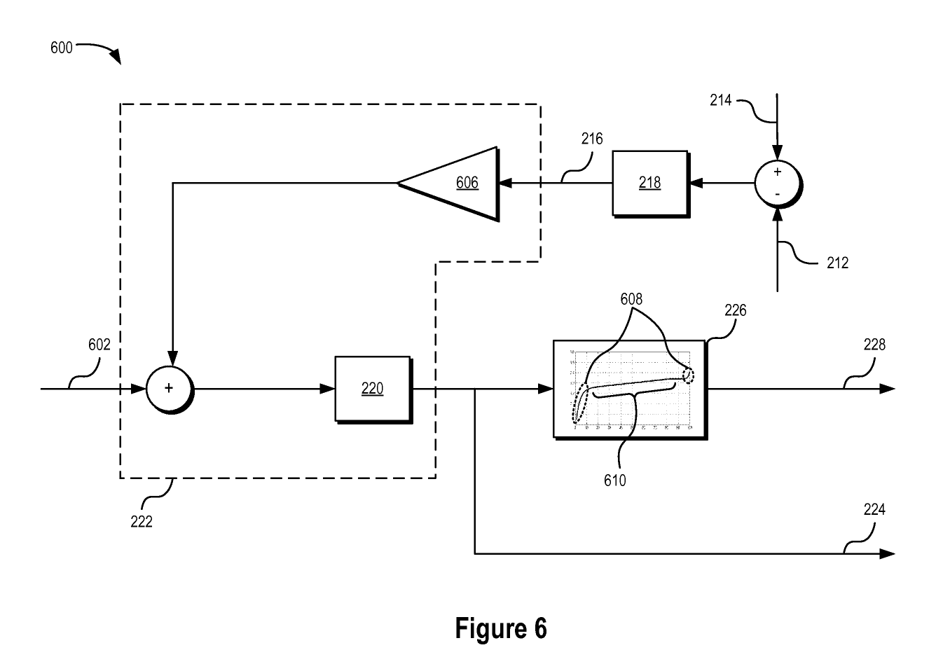

FIG. 6 illustrates a functional block diagram of a weighted system 600 for determining an SOC consistent with embodiments disclosed herein. As discussed above, in certain embodiments, a blending technique utilizing an Ah-based SOC determination and an OCV-based SOC determination may be used in connection with in estimating a state of a battery system. In certain embodiments, the weighted system 600 may receive measured current signal 602 (e.g., a measured current signal) from the battery system. The measured current signal 602 may be offset-adjusted according to an adjustment signal 216 that, in certain embodiments, may be weighted by a weighting module 606. The adjustment signal 216 may comprise an OCV difference signal between a modeled voltage 212 and a measured voltage 214 of the actual battery system, and may be generated by a ARTFC module 218 that may further employ low-pass filtering of the input signal to generate the DC-output 216. The weight gain of module 606 may be adjusted based on a confidence-tradeoff between an Ah-based and voltage based method.

The adjusted current signal may be provided to a SOC calculation module 220 configured to calculate a SOC of the battery system therefrom (e.g., based on Coulomb counting) and generate an associated SOC signal 224. The SOC signal 224 may be provided to a SOC/OCV lookup table, which may be a characteristic of the battery type. In certain areas of SOC, a voltage-based SOC correction may be applied to the SOC signal 224 whereas in other areas, a voltage-based SOC correction may not be applied. For example, in areas 608, a voltage-based correction may be applied, whereas in area 610, a voltage-based correction may not be applied. The lookup-table 226 may output an associated OCV model signal 228 to a multi-RC circuit model 208 in modeling a terminal voltage 212 of the actual battery system. The SOC signal 224 of the battery may be used as an input to a variety of vehicle and/or battery operations.

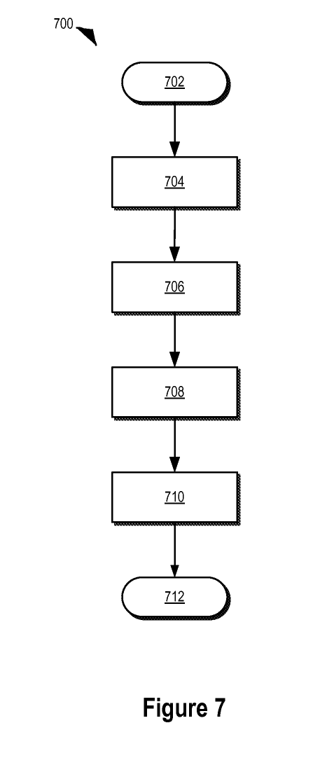

FIG. 7 illustrates a flow chart of an exemplary method 700 for determining a state of a battery system consistent with embodiments disclosed herein. In certain embodiments, method 700 may be utilized in determining a SOC of a battery system, although other battery system states may also be determined using similar methods. At 702, the method may initiate. At 704, a current measurement signal may be received from a subdivision of battery system. In certain embodiments, the subdivision may comprise, for example, a battery cell, a battery pack, and/or any other subdivision of a battery system or an entirety of a battery system. At 706, a difference signal associated with a difference between a measured voltage of the battery subdivision and a modeled voltage of the battery subdivision may be received, and used to correct the modeled OCV and SOC.

The modeled opened circuit voltage of the battery subdivision may be provided by a model of the battery subdivision. In certain embodiments, the model of the subdivision may comprise a multi-RC circuit model that includes a plurality of paired resistors and capacitors. Each of the plurality of capacitors may have capacitances associated with predefined time constants. Further, each of the plurality of resistors may have resistances estimated based, to some degree, on a measured parameter of the subdivision. In certain embodiments, the resistances may be estimated using a state observer that, in some embodiments, may be a Luenberger observer.

At 708, a correction to the received current measurement signal may be applied based, at least in part, on the difference signal generated at 706 to generate a corrected current measurement signal. At 710, a state of the subdivision based on the corrected current measurement signal may be estimated. The method may proceed to terminate at 712.

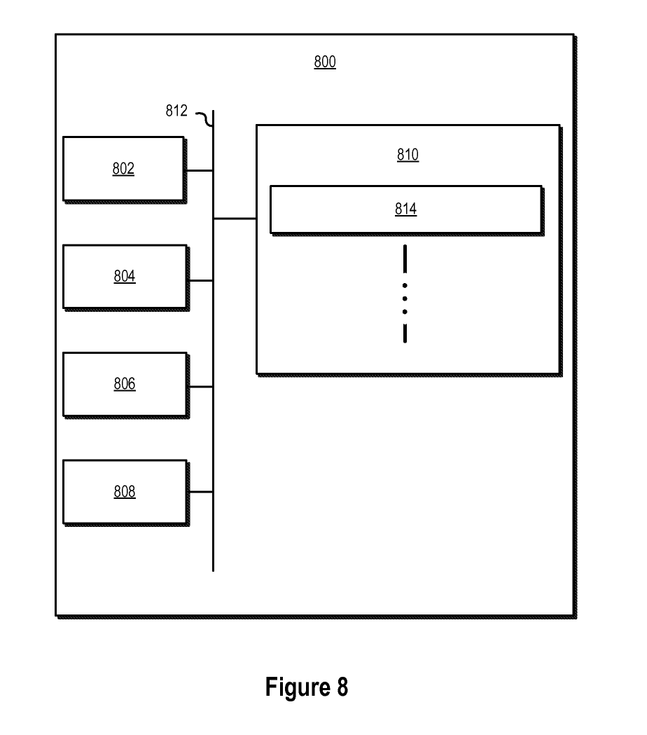

FIG. 8 illustrates an exemplary system 800 for implementing certain embodiments of the systems and methods disclosed herein. In certain embodiments, the computer system 800 may be a personal computer system, a server computer system, an on-board vehicle computer, a battery control system, and/or any other type of system suitable for implementing the disclosed systems and methods. In further embodiments, the computer system 800 may be any portable electronic computer system or electronic device including, for example, a notebook computer, a smartphone, and/or a tablet computer.

As illustrated, the computer system 800 may include, among other things, one or more processors 802, random access memory (“RAM”) 804, a communications interface 806, a user interface 808, and a non-transitory computer-readable storage medium 810. The processor 802, RAM 804, communications interface 806, user interface 808, and computer-readable storage medium 810 may be communicatively coupled to each other via a common data bus 812. In some embodiments, the various components of the computer system 800 may be implemented using hardware, software, firmware, and/or any combination thereof.

User interface 808 may include any number of devices allowing a user to interact with the computer system 800. For example, user interface 808 may be used to display an interactive interface to a user. The user interface 808 may be a separate interface system communicatively coupled with the computer system 800 or, alternatively, may be an integrated system such as a display interface for a laptop or other similar device. In certain embodiments, the user interface 808 may be produced on a touch screen display. The user interface 808 may also include any number of other input devices including, for example, keyboard, trackball, and/or pointer devices.

The communications interface 806 may be any interface capable of communicating with other computer systems, peripheral devices, and/or other equipment communicatively coupled to computer system 800. For example, the communications interface 806 may allow the computer system 800 to communicate with other computer systems (e.g., computer systems associated with external databases and/or the Internet), allowing for the transfer as well as reception of data from such systems. The communications interface 806 may include, among other things, a modem, a satellite data transmission system, an Ethernet card, and/or any other suitable device that enables the computer system 800 to connect to databases and networks, such as LANs, MANs, WANs and the Internet.

Processor 802 may include one or more general purpose processors, application specific processors, programmable microprocessors, microcontrollers, digital signal processors, FPGAs, other customizable or programmable processing devices, and/or any other devices or arrangement of devices that are capable of implementing the systems and methods disclosed herein.

Processor 802 may be configured to execute computer-readable instructions stored on non-transitory computer-readable storage medium 810. Computer-readable storage medium 810 may store other data or information as desired. In some embodiments, the computer-readable instructions may include computer executable functional modules 814. For example, the computer-readable instructions may include one or more functional modules configured to implement all or part of the functionality of the systems and methods described above. Specific functional models that may be stored on computer-readable storage medium 810 may include a module configured to model a battery system (e.g., using a multi-RC electric circuit model or the like), a module configured to implement a state observer, a module configured to implement signal blending and/or weighting (e.g., blending an Ah-based SOC determination and an OCV-based SOC determination in estimating a state of battery system), and/or any other module or modules configured to implement the systems and methods disclosed herein.

The system and methods described herein may be implemented independent of the programming language used to create the computer-readable instructions and/or any operating system operating on the computer system 800. For example, the computer-readable instructions may be written in any suitable programming language, examples of which include, but are not limited to, C, C++, Visual C++, and/or Visual Basic, Java, Perl, or any other suitable programming language, or implemented in a suitable graphical environment (e.g., a graphical simulator or the like). Further, the computer-readable instructions and/or functional modules may be in the form of a collection of separate programs or modules, and/or a program module within a larger program or a portion of a program module. The processing of data by computer system 800 may be in response to user commands, results of previous processing, or a request made by another processing machine. It will be appreciated that computer system 800 may utilize any suitable operating system including, for example, Unix, DOS, Android, Symbian, Windows, iOS, OSX, Linux, and/or the like.

Although the foregoing has been described in some detail for purposes of clarity, it will be apparent that certain changes and modifications may be made without departing from the principles thereof. It is noted that there are many alternative ways of implementing both the processes and systems described herein. Accordingly, the present embodiments are to be considered illustrative and not restrictive, and the invention is not to be limited to the details given herein, but may be modified within the scope and equivalents of the appended claims.

The foregoing specification has been described with reference to various embodiments. However, one of ordinary skill in the art will appreciate that various modifications and changes can be made without departing from the scope of the present disclosure. For example, various operational steps, as well as components for carrying out operational steps, may be implemented in alternate ways depending upon the particular application or in consideration of any number of cost functions associated with the operation of the system. Accordingly, any one or more of the steps may be deleted, modified, or combined with other steps. Further, this disclosure is to be regarded in an illustrative rather than a restrictive sense, and all such modifications are intended to be included within the scope thereof. Likewise, benefits, other advantages, and solutions to problems have been described above with regard to various embodiments. However, benefits, advantages, solutions to problems, and any element(s) that may cause any benefit, advantage, or solution to occur or become more pronounced, are not to be construed as a critical, a required, or an essential feature or element.

As used herein, the terms “comprises” and “includes,” and any other variation thereof, are intended to cover a non-exclusive inclusion, such that a process, a method, an article, or an apparatus that comprises a list of elements does not include only those elements but may include other elements not expressly listed or inherent to such process, method, system, article, or apparatus. Also, as used herein, the terms “coupled,” “coupling,” and any other variation thereof are intended to cover a physical connection, an electrical connection, a magnetic connection, an optical connection, a communicative connection, a functional connection, and/or any other connection.

Those having skill in the art will appreciate that many changes may be made to the details of the above-described embodiments without departing from the underlying principles of the invention. The scope of the present invention should, therefore, be determined only by the following claims.

1. A method of determining a state of a subdivision of a battery system, the method comprising:
receiving a current measurement signal from the subdivision;
receiving a difference signal associated with a difference between a measured open circuit voltage of the subdivision and a modeled open circuit voltage generated from a model of the subdivision;
applying a correction to the received current measurement signal based, at least in part, on the difference signal to generate a corrected current measurement signal; and
estimating a state of the subdivision based on the corrected current measurement signal.

2. The method of claim 1, wherein the state of the subdivision comprises a state of charge of the subdivision.

3. The method of claim 1, wherein the subdivision comprises a battery cell of the battery system.

4. The method of claim 1, wherein the subdivision comprises a battery pack of the battery system.

5. The method of claim 1, wherein the model of the subdivision comprises a multi-RC circuit model comprising a plurality of resistors and a plurality of capacitors.

6. The method of claim 5, wherein each of the plurality of capacitors have capacitances associated with predefined time constants.

7. The method of claim 5, wherein each of the plurality of resistors have resistances estimated based on a measured parameter of the subdivision.

8. The method of claim 7, wherein the resistances are estimated using a state observer, the resistances being a state parameter of the state observer.

9. The method of claim 8, wherein the state observer comprises a Luenberger observer.

10. The method of claim 1, wherein the method further comprises applying an approximative real-time Fourier transform to the difference signal prior to applying the correction.

11. A non-transitory computer-readable medium comprising instructions that, when executed by a processor, cause the processor to perform a method of determining a state of a subdivision of a battery system comprising:
receiving a current measurement signal from the subdivision;
receiving a difference signal associated with a difference between a measured open circuit voltage of the subdivision and a modeled open circuit voltage generated from a model of the subdivision;
applying a correction to the received current measurement signal based, at least in part, on the difference signal to generate a corrected current measurement signal; and
estimating a state of the subdivision based on the corrected current measurement signal.

12. The non-transitory computer-readable medium of claim 11, wherein the state of the subdivision comprises a state of charge of the subdivision.

13. The non-transitory computer-readable medium of claim 11, wherein the subdivision comprises a battery cell of the battery system.

14. The non-transitory computer-readable medium of claim 11, wherein the subdivision comprises a battery pack of the battery system.

15. The non-transitory computer-readable medium of claim 11, wherein the model of the subdivision comprises a multi-RC circuit model comprising a plurality of resistors and a plurality of capacitors.

16. The non-transitory computer-readable medium of claim 15, wherein each of the plurality of capacitors have capacitances associated with predefined time constants.

17. The non-transitory computer-readable medium of claim 15, wherein each of the plurality of resistors have resistances estimated based on a measured parameter of the subdivision.

18. The non-transitory computer-readable medium of claim 17, wherein the resistances are estimated using a state observer, the resistances being a state parameter of the state observer.

19. The non-transitory computer-readable medium of claim 18, wherein the state observer comprises a Luenberger observer.

20. The non-transitory computer-readable medium of claim 1, wherein instructions are further configured to cause the processor to apply an approximative real-time Fourier transform to the difference signal prior to applying the correction.
